(19) United States
(12) Patent Application Publication
(10) Pub. No.: US 2025/0338656 A1
(43) Pub. Date: Oct. 30, 2025

(54) IMAGE SENSOR

(71) Applicant: VisEra Technologies Company Ltd., Hsin-Chu City (TW)

(72) Inventors: Yu-Fu WU, Hsin-Chu City (TW); Chun-Yuan WANG, Hsin-Chu City (TW); Po-Hsiang WANG, Hsin-Chu City (TW); Chih-Ming WANG, Hsin-Chu City (TW)

(21) Appl. No.: 18/650,728

(22) Filed: Apr. 30, 2024

(51) Int. Cl. H01L 27/146

(52) U.S. Cl. CPC H10F 39/806; H10F 39/8053

(57) ABSTRACT

Some embodiments of the present disclosure provide an image sensor, including a substrate, a plurality of first photodiodes, a first color filter unit and a first light intensity distributor. The first photodiodes are in the substrate. The first color filter unit is over the substrate. The first color filter unit includes a top-left region, a top region, a top-right region, a left region, a center region, a right region, a bottom-left region, a bottom region, and a bottom-right region over the first photodiodes, respectively. The first light intensity distributor is over the first color filter unit, in which the first light intensity distributor includes a plurality of first nanopillars configured to converge light to the center region or disperse light from the center region, and the center region has a highest or a lowest optical intensity.

### BACKGROUND

### Field of Disclosure

The present disclosure relates to an image sensor.

### Description of Related Art

Image sensors, such as complementary metal oxide semiconductor (CMOS) image sensors (also known as CIS), are widely used in various image-capturing apparatus such as digital still-image cameras, digital video cameras, and the like. The light-sensing portion of the image sensor may detect ambient color change, and signal electric charges may be generated depending on the amount of light received in the light-sensing portion. The light-sensing portion may include photodiodes. In addition, the signal electric charges generated in the light-sensing portion may be transmitted and amplified, to obtain an image signal.

Image sensors should be able to capture images quickly, and the accuracy, spatial resolution, and dynamic range must be as high as possible. Conventionally, there are two different ways to create the difference of the amount of light received in different light-sensing portion to achieve high dynamic range (HDR). The first one, time enabling HDR, may be achieved by exposing different photodiodes by different duration. However, time enabling HDR may also cause motion artifact. The second one, structure enabling HDR, may be achieved by disposing different sizes of the micro-lens over the photodiodes, or disposing a light-shield over a portion of the photodiodes, so that a portion of the photodiodes may receive large amount of light. However, the process of producing different sizes of the micro-lens may be complicated, or the light-shield may cause too much energy loss. Therefore, a novel image sensor capable of achieving HDR imaging is called for.

### SUMMARY

Some embodiments of the present disclosure provide an image sensor, including a substrate, a plurality of first photodiodes, a first color filter unit and a first light intensity distributor. The first photodiodes are in the substrate. The first color filter unit is over the substrate in a cross-section view. The first color filter unit includes a top-left region, a top region, a top-right region, a left region, a center region, a right region, a bottom-left region, a bottom region, and a bottom-right region in a top view. The first light intensity distributor is over the first color filter unit, in which the first light intensity distributor includes a plurality of first nanopillars configured to distribute light to make the center region has a highest or a lowest optical intensity.

In some embodiments, the first nanopillars include a first pattern of the first nanopillars in the left region and a second pattern of the first nanopillars in the right region, the first pattern of the first nanopillars is symmetric to the second pattern of the first nanopillars, with a symmetric axis passing through centers of the top region and the bottom region.

In some embodiments, the first nanopillars include a first pattern of the first nanopillars in the top region and a second pattern of the first nanopillars in the bottom region, the first pattern of the first nanopillars is symmetric to the second pattern of the first nanopillars, with a symmetric axis passing through centers of the left region and the right region.

In some embodiments, the first nanopillars include a first pattern of the first nanopillars in the top-left region and a second pattern of the first nanopillars in the bottom-right region, the first pattern of the first nanopillars is symmetric to the second pattern of the first nanopillars, with a symmetric axis passing through centers of the top-right region and the bottom-left region.

In some embodiments, the first nanopillars include a first pattern of the first nanopillars in the top-right region and a second pattern of the first nanopillars in the bottom-left region, the first pattern of the first nanopillars is symmetric to the second pattern of the first nanopillars, with a symmetric axis passing through centers of the top-left region and the bottom-right region.

In some embodiments, the first nanopillars include a first pattern of the first nanopillars in the left region, the right region, the top region, the bottom region, the top-left region, the top-right region, the bottom-left region and the bottom-right region and a second pattern of the first nanopillars in the center region, the first pattern of the first nanopillars is used to converge light to the left region, the right region, the top region, the bottom region, the top-left region, the top-right region, the bottom-left region and the bottom-right region, the second pattern of the first nanopillars is used to disperse light from the center region, the first pattern of the first nanopillars is centrosymmetric with a symmetric point at the center of the center region, and individual patterns of the first nanopillars in the left region, the right region, the top region, the bottom region, the top-left region, the top-right region, the bottom-left region and the bottom-right region are the same or different.

In some embodiments, the first nanopillars include a first pattern of the first nanopillars in the left region, the right region, the top region, the bottom region, the top-left region, the top-right region, the bottom-left region and the bottom-right region and a second pattern of the first nanopillars in the center region, the first pattern of the first nanopillars are used to disperse light from the left region, the right region the top region, the bottom region, the top-left region, the top-right region, the bottom-left region and the bottom-right region, and the second pattern of the first nanopillars is used to converge light to the center region, the first pattern of the first nanopillars is centrosymmetric with a symmetric point at the center of the center region, and individual patterns of the first nanopillars in the left region, the right region, the top region, the bottom region, the top-left region, the top-right region, the bottom-left region and the bottom-right region are the same or different.

In some embodiments, the first nanopillars include first central nanopillars at centers of the top region, the bottom region, the left region, the right region, the top-left region, the top-right region, the bottom-left region and bottom-right region and a second central nanopillar at a center of the center region, and a volume of each of the first central nanopillars is more than 4 times larger than a volume of the second central nanopillar.

In some embodiments, the first nanopillars include first central nanopillars at centers of the top region, the bottom region, the left region, the right region, the top-left region, the top-right region, the bottom-left region and bottom-right region and a second central nanopillar at a center of the center region, and a volume of each of the first central nanopillars is less than 4 times smaller than a volume of the second central nanopillar.

In some embodiments, the first light intensity distributor further includes an under layer under the first nanopillars, and a refractive index of the first nanopillars is larger than a refractive index of the under layer.

In some embodiments, the first light intensity distributor further includes a dielectric layer under the first nanopillars and over the under layer, and the dielectric layer and the first nanopillars are made of same materials.

In some embodiments, the first nanopillars include a plurality of lower nanopillars over the first color filter unit and a plurality of upper nanopillars over the lower nanopillars.

In some embodiments, first light intensity distributor further includes a protective layer over the first nanopillars, the first nanopillars are embedded in the protective layer, and a refractive index of the first nanopillars is larger than a refractive index of the protective layer.

In some embodiments, the first light intensity distributor further includes a light-shielding layer, in which the light-shielding layer is under the center region of the first color filter unit when the center region has the lowest optical intensity, or the light-shielding layer is under at least one of the top-left region, the top region, the top-right region, the left region, the right region, the bottom-left region, the bottom region, and the bottom-right region of the first color filter unit when the center region has the highest optical intensity.

In some embodiments, the top region, the left region, the right region and the bottom region have same area sizes, the top-left region, the top-right region, the bottom-left region and the bottom-right region have same area sizes, an area ratio of the center region, the top region and the top-left region is 1:1:1, and each of the top-left region, the top region, the top-right region, the left region, the center region, the right region, the bottom-left region, the bottom region, and the bottom-right region corresponds with one of the first photodiodes respectively.

In some embodiments, the top region, the left region, the right region and the bottom region have same area sizes, the top-left region, the top-right region, the bottom-left region and the bottom-right region have same area sizes, an area ratio of the center region, the top region and the top-left region is 4:2:1, and the center region corresponds with four of the first photodiodes, each of the top region, the left region, the right region and the bottom region corresponds with two of the first photodiodes respectively, and each of the top-left region, the top-right region, the bottom-left region and the bottom-right region corresponds with one of the first photodiodes respectively.

In some embodiments, the top region, the left region, the right region and the bottom region have same area sizes, the top-left region, the top-right region, the bottom-left region and the bottom-right region have same area sizes, an area ratio of the center region, the top region and the top-left region is 9:3:1, and the center region corresponds with nine of the first photodiodes, each of the top region, the left region, the right region and the bottom region corresponds with three of the first photodiodes respectively, and each of the top-left region, the top-right region, the bottom-left region and the bottom-right region corresponds with one of the first photodiode respectively.

In some embodiments, the top region, the left region, the right region and the bottom region have same area sizes, the top-left region, the top-right region, the bottom-left region and the bottom-right region have same area sizes, an area ratio of the center region, the top region and the top-left region is 1:2:4, and the center region corresponds with one of the first photodiodes, each of the top region, the left region, the right region and the bottom region corresponds with two of the first photodiodes respectively, and each of the top-left region, the top-right region, the bottom-left region and the bottom-right region corresponds with four of the first photodiodes respectively.

In some embodiments, the first color filter unit is laterally shifted relative to the first photodiodes towards a center of the image sensor, and the first light intensity distributor is laterally shifted relative to the first color filter unit towards the center of the image sensor.

In some embodiments, the image sensor further includes a plurality of second photodiodes, a second color filter unit, a second light intensity distributor, a plurality of third photodiodes, a third color filter unit and a third light intensity distributor. The second photodiodes are in the substrate. The second color filter unit is over the substrate and the second photodiodes. The second light intensity distributor is over the second color filter unit, in which the second light intensity distributor includes a plurality of second nanopillars. The third photodiodes are in the substrate. The third color filter unit is over the substrate and the third photodiodes. The third light intensity distributor is over the third color filter unit, in which the third light intensity distributor includes a plurality of third nanopillars. The first color filter unit, the second color filter unit and the third color filter unit have the same color, but are at different locations of the image sensor. A distance between centers of the second light intensity distributor and the first light intensity distributor and a distance between centers of the third light intensity distributor and the first light intensity distributor are the same, an angle between a line passing through the centers of the second light intensity distributor and the first light intensity distributor and a line passing through the centers of the third light intensity distributor and the first light intensity distributor is 90 degrees, and a pattern of the second nanopillars is the same as a pattern of the third nanopillars after rotating the second light intensity distributor 90 degrees clockwise.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a top view of an image sensor in some embodiments of the present disclosure.

FIG. 2A illustrates an enlargement view of a portion of the top view of an image sensor in some embodiments of the present disclosure. FIG. 2B illustrates a cross-section view taken along line A-A′ of FIG. 2A.

FIG. 3A illustrates an enlargement view of a portion of the top view of an image sensor in some other embodiments. FIG. 3B illustrates a cross-section view taken along line A-A′ of FIG. 3A.

FIG. 4A illustrates an enlargement view of a portion of the top view of an image sensor in some other embodiments. FIG. 4B illustrates a cross-section view taken along line A-A′ of FIG. 4A.

FIG. 5A illustrates an enlargement view of a portion of the top view of an image sensor in some other embodiments. FIG. 5B illustrates a cross-section view taken along line A-A′ of FIG. 5A.

FIGS. 6A-6D illustrate different patterns of the nanopillars in some embodiments of the present disclosure.

FIGS. 7A-7E illustrate different patterns of the nanopillars in some embodiments of the present disclosure.

FIGS. 8A and 8B illustrate a top view of the nanopillars in some embodiments of the present disclosure.

FIGS. 9A-9G illustrate various examples of top views of the nanopillars in some embodiments of the present disclosure.

FIG. 10 illustrates a top view of the color filter unit in some other embodiments of the present disclosure.

FIGS. 11A-11B illustrate a top view of the color filter unit in some other embodiments.

FIG. 12 illustrates a cross-section of an image sensor in some other embodiments.

FIG. 13 illustrates a cross-section of an image sensor in some other embodiments.

FIG. 14 illustrates a cross-section of an image sensor in some other embodiments.

FIG. 15 illustrates a cross-section of an image sensor in some other embodiments.

FIG. 16 illustrates a top view of an image sensor in some other embodiments.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

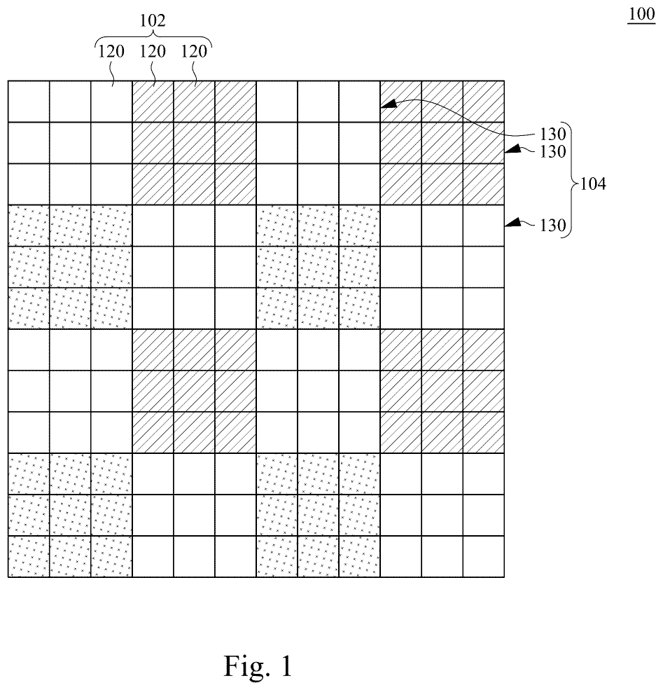

FIG. 1 illustrates a top view of an image sensor 100 in some embodiments of the present disclosure. The image sensor 100 includes a pixel array 102 covered by a color filter array 104. The pixel array 102 includes multiple photodiodes 120. The photodiodes 120 may be a low sensitivity photodiode or a high sensitivity photodiode. The low sensitivity photodiodes and the high sensitivity photodiodes are arranged in a specific form, which will be discussed later. The color filter array 104 is over the pixel array 102, and the color filter array 104 includes multiple color filter units 130. Each color filter units 130 correspond with a color. The color filter array 104 may be a Bayer pattern including three different kinds of color filter units 130. For example, The color filter array 104 may be a RGGB filter (i.e. 50% of the color filter units 130 of the color filter array 104 are green light filter, 25% of the color filter units 130 of the color filter array 104 are red light filter, and 25% of the color filter units 130 of the color filter array 104 are blue light filter) or a RCCB filter (i.e. 50% of the color filter units 130 of the color filter array 104 are clear filter, 25% of the color filter units 130 of the color filter array 104 are red light filter, and 25% of the color filter units 130 of the color filter array 104 are blue light filter). It is noted that the technical characteristics in the following descriptions may be applicable for at least one kind of color filter unit in the image sensor 100, and may be or may be not applicable for other kinds of color filter unit in the image sensor 100. Each of the color filter units 130 corresponds with more than one photodiodes 120. In some embodiments, the color filter units 130 may correspond with 9 photodiodes 120, as shown in FIG. 1.

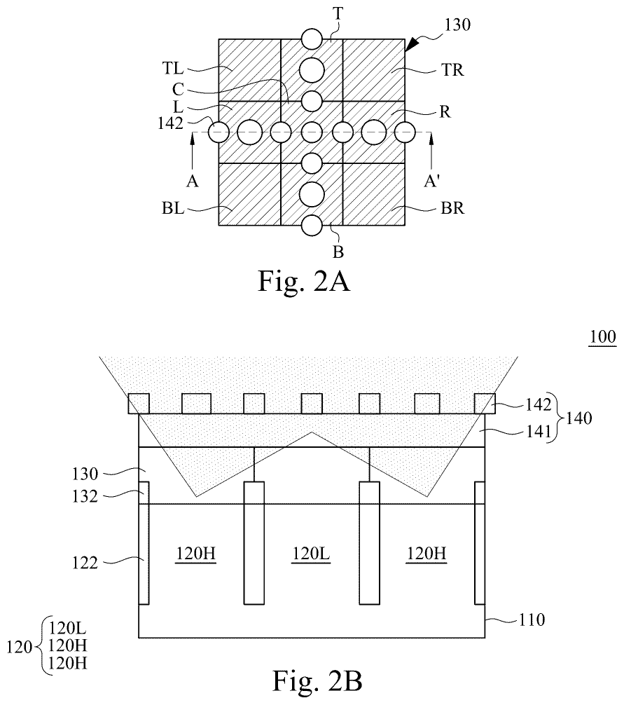

FIG. 2A illustrates an enlargement view of a portion of the top view of an image sensor 100 in some embodiments of the present disclosure. FIG. 2B illustrates a cross-section view taken along line A-A′ of FIG. 2A. Refer to FIGS. 2A and 2B, the image sensor 100 includes a substrate 110, a plurality of photodiodes 120, a color filter unit 130 and a light intensity distributor 140. The substrate 110 may be a semiconductor substrate, for example, silicon substrate. Furthermore, in some embodiments, the semiconductor substrate may also be an elemental semiconductor including germanium, a compound semiconductor including gallium nitride (GaN), silicon carbide (SiC), gallium arsenide (GaAs), gallium phosphide (GaP), indium phosphide (InP), indium arsenide (InAs), and/or indium antimonide (InSb), an alloy semiconductor including silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenide phosphide (GaInAsP) alloy, or a combination thereof.

The photodiodes 120 are in the substrate 110. The color filter unit 130 is over the substrate 110, and the color filter unit 130 includes a top-left region TL, a top region T, a top-right region TR, a left region L, a center region C, a right region R, a bottom-left region BL, a bottom region B, and a bottom-right region BR over the photodiodes 120, respectively. The top region T, the left region L, the right region R and the bottom region B have same area sizes, the top-left region TL, the top-right region TR, the bottom-left region BL and the bottom-right BR region have same area sizes, and an area ratio of the center region C, the top region T and the top-left region TL is 1:1:1. The photodiodes 120 includes a low sensitivity photodiode 120L and a plurality of high sensitivity photodiodes 120H. The low sensitivity photodiode 120L is under the center region C of the color filter unit 130, and one of the high sensitivity photodiodes 120H is under each of the top-left region TL, the top region T, the top-right region TR, the left region L, the right region R, the bottom-left region BL, the bottom region B, and the bottom-right region BR of the color filter unit 130. That is, each of the top region T, the left region L, the right region R and the bottom region B, the center region C, the top-left region TL, the top-right region TR, the bottom-left region BL and the bottom-right BR region corresponds with 1 photodiode 120. In the present disclosure, the term “a certain region corresponds with a certain number of the photodiodes” means that “a certain number of the photodiodes are directly below a certain region”. The adjacent photodiodes 120 are separated by the deep trench isolations (DTI). In some embodiments, the deep trench isolations 122 are made of silicon oxide. In some embodiments, the color filter unit 130 further includes light shields 132 between different regions of the color filter unit 130.

The light intensity distributor 140 is over the color filter unit 130, and the light intensity distributor 140 includes a plurality of nanopillars 142 configured to distribute light to make the center region C has a highest or lowest optical intensity. For example, in FIGS. 2A and 2B, the light intensity distributor 140 includes a plurality of nanopillars 142 configured to disperse light from the center region C, in which the center region C has a lowest optical intensity. Specifically, the pattern of the nanopillars 142 is centrosymmetric with a symmetric point at the center of the center region C, and some of the nanopillars 142 over the top region T, the left region L, the right region R, and the bottom region B may be larger than the nanopillars 142 over the center region C. When the image sensor 100 receive light and light passes through the light intensity distributor 140, the light is dispersed from the center region C, thereby the center region C has the lowest light intensity. The low sensitivity photodiode 120L under the center region C receives less light than the high sensitivity photodiode 120H under the top-left region TL, the top region T, the top-right region TR, the left region L, the right region R, the bottom-left region BL, the bottom region B, and the bottom-right region BR. The light intensity distributor 140 further includes an under layer 141 under the nanopillars 142, and a refractive index of the nanopillars 142 is larger than a refractive index of the under layer 141 and a refractive index of the surrounding environment. In some embodiments, the diameter of the nanopillars 142 is within the scale of the sub-wavelength of the light received by the image sensor 100.

In the present disclosure, the light intensity distributor 140 may be formed by forming the under layer 141 over the color filter unit 130, and then forming the nanopillars 142 over the under layer 141. The nanopillars 142 may be formed by first forming a nanopillar material layer over the under layer 141, and then etching the nanopillar material layer to form the nanopillars 142. The nanopillars 142 with all sizes are formed during the same etching process. Therefore, the manufacturing process of the light intensity distributor 140 is simple, and the cost of manufacturing the light intensity distributor 140 is reduced. Moreover, the arrangement and the shape of the nanopillars 142 may directly distribute the light received by the image sensor 100 into different regions without shielding certain portions of the photodiodes 120. Therefore, there is no significant energy loss with the image sensor 100 in some embodiments of the present disclosure.

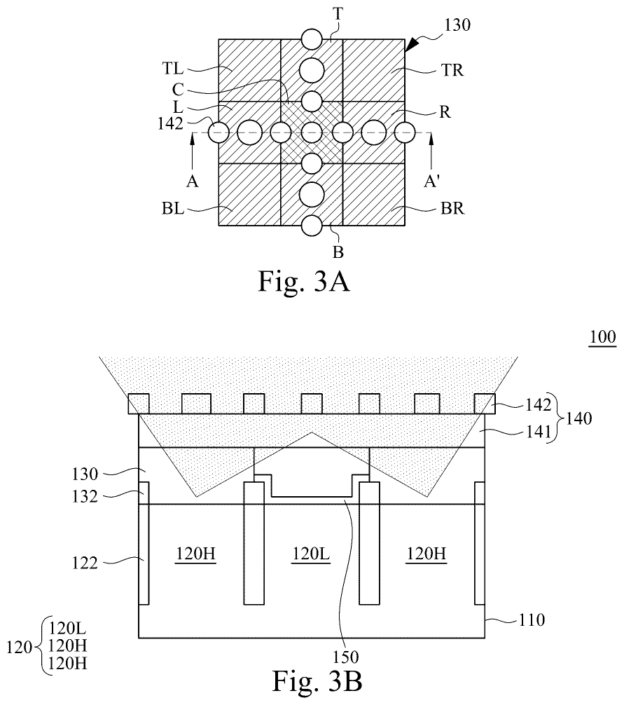

FIG. 3A illustrates an enlargement view of a portion of the top view of an image sensor 100 in some other embodiments. FIG. 3B illustrates a cross-section view taken along line A-A′ of FIG. 3A. The image sensor 100 in FIGS. 3A and 3B is similar to the image sensor 100 in FIGS. 2A and 2B. The difference is that the image sensor 100 in FIGS. 3A and 3B further includes a light-shielding layer 150. The light-shielding layer 150 is under the center region C of the color filter unit 130 when the center region C has the lowest optical intensity.

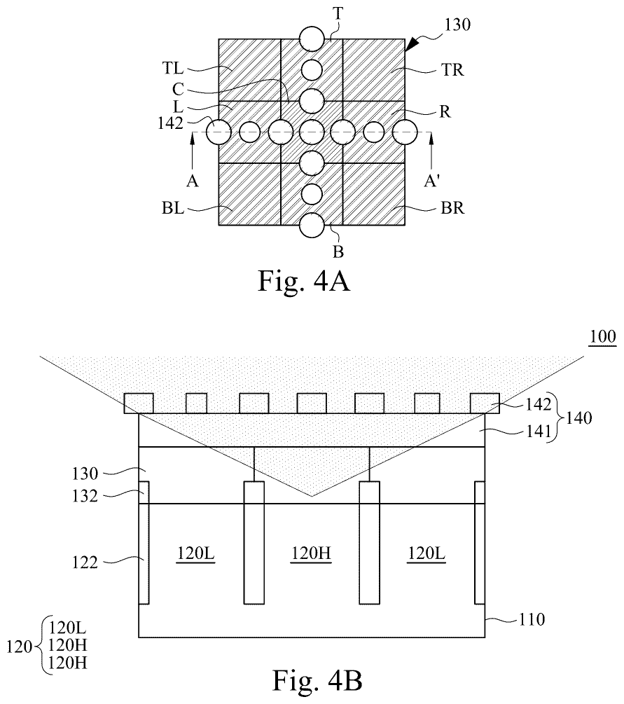

FIG. 4A illustrates an enlargement view of a portion of the top view of an image sensor 100 in some other embodiments. FIG. 4B illustrates a cross-section view taken along line A-A′ of FIG. 4A. The image sensor 100 in FIGS. 4A and 4B is similar to the image sensor 100 in FIGS. 2A and 2B. The difference is that in FIGS. 4A and 4B, the high sensitivity photodiode 120H is under the center region C of the color filter unit 130, and one of the low sensitivity photodiodes 120L is under each of the top-left region TL, the top region T, the top-right region TR, the left region L, the right region R, the bottom-left region BL, the bottom region B, and the bottom-right region BR of the color filter unit 130. The light intensity distributor 140 includes a plurality of nanopillars 142 configured to converge light to the center region C, in which the center region C has a highest optical intensity. Specifically, the pattern of the nanopillars 142 is centrosymmetric with a symmetric point at the center of the center region C, and some of the nanopillars 142 over the top region T, the left region L, the right region R, and the bottom region B may be smaller than the nanopillars 142 over the center region C. When the image sensor 100 receive light and light passes through the light intensity distributor 140, the light is converged to the center region C, thereby the center region C has the highest light intensity. The high sensitivity photodiode 120H under the center region C receives more light than the low sensitivity photodiodes 120L under the top-left region TL, the top region T, the top-right region TR, the left region L, the right region R, the bottom-left region BL, the bottom region B, and the bottom-right region BR.

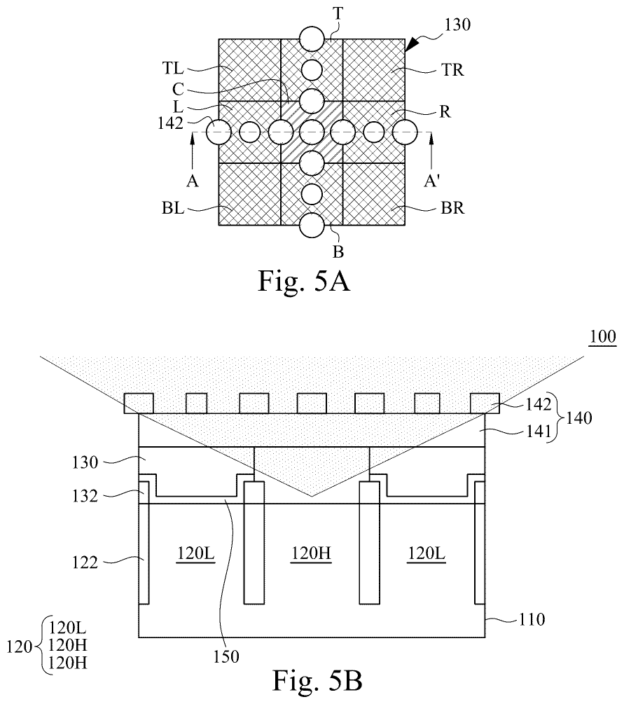

FIG. 5A illustrates an enlargement view of a portion of the top view of an image sensor 100 in some other embodiments. FIG. 5B illustrates a cross-section view taken along line A-A′ of FIG. 5A. The image sensor 100 in FIGS. 5A and 5B is similar to the image sensor 100 in FIGS. 4A and 4B. The difference is that the image sensor 100 in FIGS. 5A and 5B further includes a light-shielding layer 150. The light-shielding layer 150 is under at least one of the top-left region TL, the top region T, the top-right region TR, the left region L, the right region R, the bottom-left region BL, the bottom region B, and the bottom-right region BR of the color filter unit 130 when the center region C has the highest optical intensity.

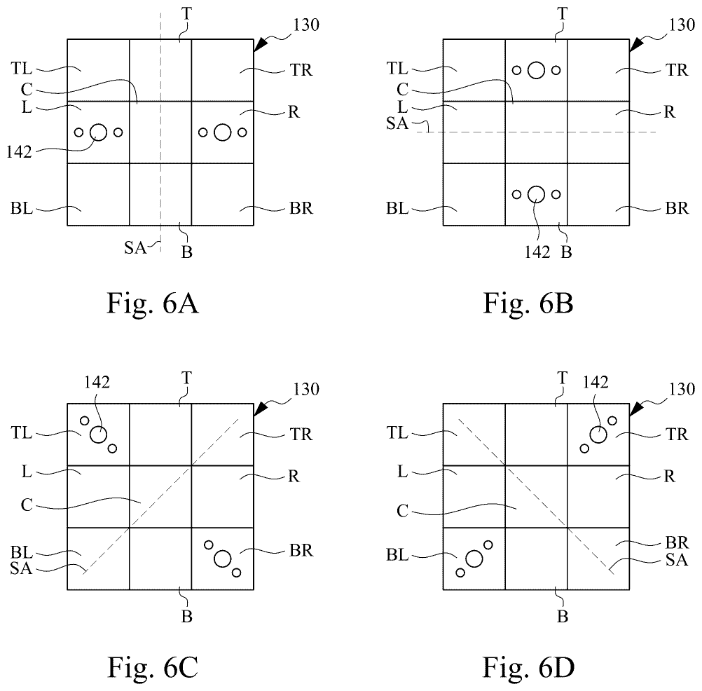

FIGS. 6A-6D illustrate different patterns of the nanopillars 142 in some embodiments of the present disclosure. Refer to FIG. 6A. The nanopillars 142 include a first pattern of the nanopillars 142 in the left region L and a second pattern of the nanopillars 142 in the right region R, the first pattern of the nanopillars 142 is symmetric to the second pattern of the nanopillars 142, with a symmetric axis SA passing through centers of the top region T and the bottom region B.

Refer to FIG. 6B. The nanopillars 142 include a first pattern of the nanopillars 142 in the top region T and a second pattern of the nanopillars 142 in the bottom region B, the first pattern of the nanopillars 142 is symmetric to the second pattern of the nanopillars 142, with a symmetric axis SA passing through centers of the left region L and the right region R.

Refer to FIG. 6C. The nanopillars 142 includes a first pattern of the nanopillars 142 in the top-left region TL and a second pattern of the first nanopillars in the bottom-right region BR, the first pattern of the nanopillars 142 is symmetric to the second pattern of the nanopillars 142, with a symmetric axis SA passing through centers of the top-right region TR and the bottom-left region BL.

Refer to FIG. 6D. The nanopillars 142 includes a first pattern of the nanopillars 142 in the top-right region TR and a second pattern of the nanopillars 142 in the bottom-left region BL, the first pattern of the nanopillars 142 is symmetric to the second pattern of the nanopillars 142, with a symmetric axis SA passing through centers of the top-left region TL and the bottom-right region BR.

The pattern of the nanopillars 142 in FIGS. 6A-6D are centrosymmetric with a symmetric point at the center of the center region C. That is, the pattern of the nanopillars 142 can overlap the pattern of the nanopillars 142 after rotating 180 degrees. Individual patterns of the first nanopillars in the left region L, the right region R, the top region T, the bottom region B, the top-left region TL, the top-right region TR, the bottom-left region BL, and the bottom-right region BR are the same or different. Such configuration of the nanopillars 142 may be used to distribute the light to different regions of the image sensor 100.

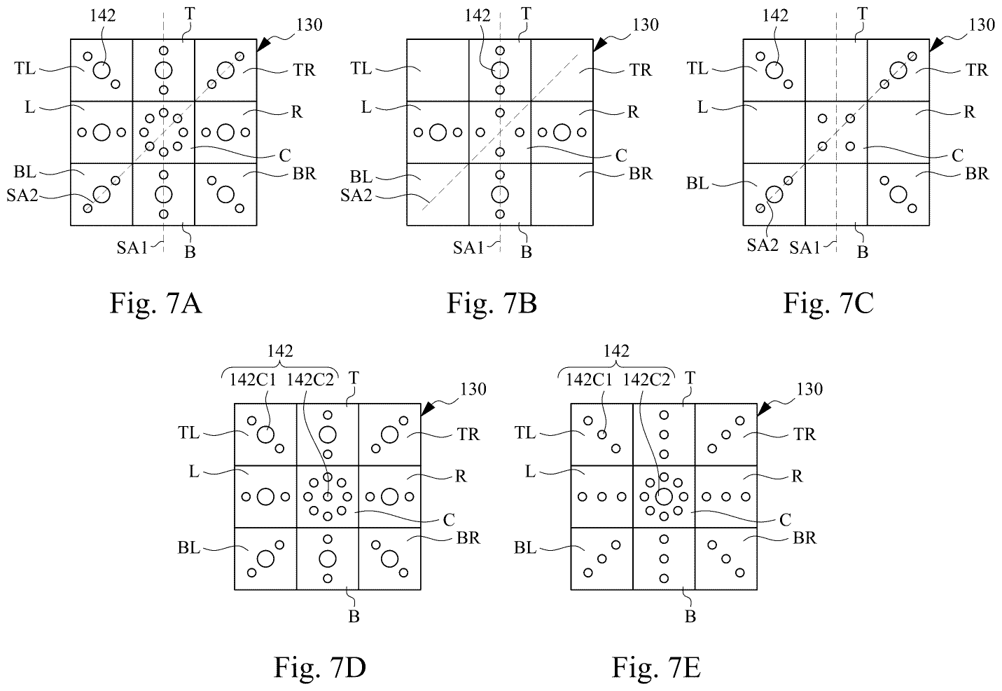

FIGS. 7A-7E illustrate different patterns of the nanopillars 142 in some embodiments of the present disclosure. Refer to FIG. 7A. The nanopillars 142 include a first pattern of the nanopillars 142 in the left region L, the right region R, the top region T, the bottom region B, the top-left region TL, the top-right region TR, the bottom-left region BL and the bottom-right region BR and a second pattern of the nanopillars 142 in the center region C. The pattern of the nanopillars 142 may have more than one symmetric axes, such as symmetric axis SA1 and SA2. For example, the symmetric axis SA1 passes through the center of the top region T and the bottom region B, and the symmetric axis SA2 passes through the center of the top-right region TR and the bottom-left region BL. In some embodiments, the symmetric axis SA1 also passes through the nanopillars 142 over the top region T, the center region C and the bottom region B, and the symmetric axis SA2 also passes through the nanopillars 142 over the top-right region TR, the center region C and the bottom-left region BL. That is, the symmetric axis SA1 and SA2 may form cross-sections of the nanopillars 142 respectively. Depend on the size of the nanopillars 142 respectively, the first pattern of the nanopillars 142 is used to converge light to (or disperse light from) the left region L, the right region R, the top region T, the bottom region B, the top-left region TL, the top-right region TR, the bottom-left region BL and the bottom-right region BR. The second pattern of the nanopillars 142 may be used to disperse light from (or converge light to) the center region C.

Refer to FIG. 7B. The nanopillars 142 includes a first pattern of the nanopillars 142 in the left region L, the right region R, the top region T and the bottom region B and a second pattern of the nanopillars 142 in the center region C. The symmetric axis SA1 passes through the nanopillars 142 over the top region T, the center region C and the bottom region B but the symmetric axis SA2 does not pass through the nanopillars 142 over the top-right region TR, the center region C and the bottom-left region BL. That is, only the symmetric axis SA1 forms a cross-section of the nanopillars 142. Depend on the size of the nanopillars 142 respectively, the first pattern of the nanopillars 142 is used to converge light to (or disperse light from) the left region L, the right region R, the top region T and the bottom region B. The second pattern of the nanopillars 142 may be used to disperse light from (or converge light to) the center region C.

Refer to FIG. 7C. The nanopillars 142 includes a first pattern of the nanopillars 142 in the top-left region TL, the top-right region TR, the bottom-left region BL and the bottom-right region BR and a second pattern of the nanopillars 142 in the center region C. The symmetric axis SA1 does not pass through the nanopillars 142 over the top region T, the center region C and the bottom region B, but the symmetric axis SA2 passes through the nanopillars 142 over the top-right region TR, the center region C and the bottom-left region BL. That is, only the symmetric axis SA2 forms a cross-section of the nanopillars 142. Depend on the size of the nanopillars 142 respectively, the first pattern of the nanopillars 142 is used to converge light to (or disperse light from) the top-left region TL, the top-right region TR, the bottom-left region BL and the bottom-right region BL. The second pattern of the nanopillars 142 may be used to disperse light from (or converge light to) the center region C.

Refer to FIG. 7D. The nanopillars 142 include a first pattern of the nanopillars 142 in the left region L, the right region R, the top region T, the bottom region B, the top-left region TL, the top-right region TR, the bottom-left region BL and the bottom-right region BR and a second pattern of the nanopillars 142 in the center region C. Moreover, the nanopillars 142 include central nanopillars 142C1 at centers of the top region T, the bottom region B, the left region L, the right region R, the top-left region TL, the top-right region TR, the bottom-left region BL and the bottom-right region BR and a central nanopillar 142C2 at a center of the center region C, and a volume of each of the central nanopillars 142C1 is more than 4 times larger than a volume of the central nanopillar 142C2. In some embodiments where the volume of the central nanopillar 142C1 is larger than the volume of the central nanopillar 142C2, the first pattern of the nanopillars 142 is used to converge light to the left region L, the right region R, the top region T, the bottom region B, the top-left region TL, the top-right region TR, the bottom-left region BL and the bottom-right region BR. The second pattern of the nanopillars 142 may be used to disperse light from the center region C.

Refer to FIG. 7E. The nanopillars 142 include a first pattern of the nanopillars 142 in the left region L, the right region R, the top region T, the bottom region B, the top-left region TL, the top-right region TR, the bottom-left region BL and the bottom-right region BR and a second pattern of the nanopillars 142 in the center region C. Moreover, the nanopillars 142 include central nanopillars 142C1 at centers of the top region T, the bottom region B, the left region L, the right region R, the top-left region TL, the top-right region TR, the bottom-left region BL and bottom-right region BR and a central nanopillar 142C2 at a center of the center region C, and a volume of each of the central nanopillars 142C1 is less than 4 times smaller than a volume of the central nanopillar 142C2. In some embodiments where the volume of the central nanopillar 142C1 is smaller than the volume of the central nanopillar 142C2, the first pattern of the nanopillars 142 is used to disperse light from the left region L, the right region R, the top region T, the bottom region B, the top-left region TL, the top-right region TR, the bottom-left region BL and the bottom-right region BR. The second pattern of the nanopillars 142 may be used to converge light to the center region C.

The pattern of the nanopillars 142 in FIGS. 7A-7E are centrosymmetric with a symmetric point at the center of the center region C. That is, the pattern of the nanopillars 142 can overlap the pattern of the nanopillars 142 after rotating 180 degrees. Individual patterns of the first nanopillars in the left region L, the right region R, the top region T, the bottom region B, the top-left region TL, the top-right region TR, the bottom-left region BL, and the bottom-right region BR are the same or different. Such configuration of the nanopillars 142 may be used to distribute the light to different regions of the image sensor 100.

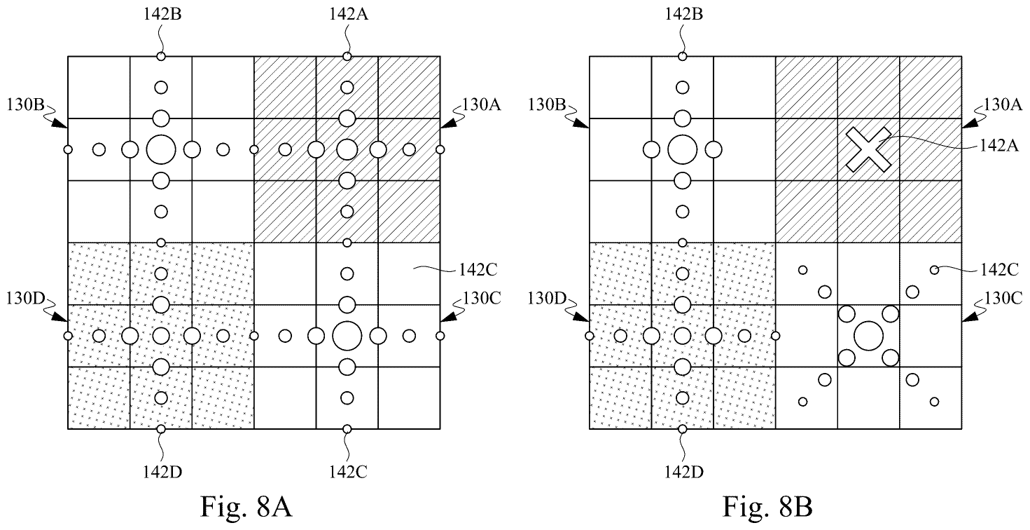

FIGS. 8A and 8B illustrate a top view of the nanopillars in some embodiments of the present disclosure. The pattern of the nanopillars may be modified for different color filter units, in which the color filter units may be used to filter different colors. For example, referring to FIG. 8A, the color filter unit 130A may be a red color filter unit, the color filter units 130B and 130C may be a clear color filter unit, and the color filter unit 130D may be a blue color filter unit. The diameters of the nanopillars 142A over the color filter unit 130A and the nanopillars 142D over the color filter unit 130D may be different from the diameters of the nanopillars 142B over the color filter unit 130B and the nanopillars 142C over the color filter unit 130C.

Refer to FIG. 8B, the shape and the arrangement of the nanopillars may be modified for different color filter units. For example, as the nanopillars 142A over the color filter unit 130A shown, the shape of the nanopillars 142A may be in other shapes rather than circle, such as crossed-shape. As the nanopillars 142B over the color filter unit 130B shown, the nanopillars 142B may be arranged over the top region, the center region and the bottom region of the color filter unit 130B. As the nanopillars 142C over the color filter unit 130C shown, the nanopillars 142 may be arranged over the top-left region, the top-right region, the center region, the bottom-left region and the bottom-right region of the color filter unit 130C. As the nanopillars 142D over the color filter unit 130D shown, the nanopillars 142D may be arranged over the left region, the top region, the center region, the bottom region and the right region of the color filter unit 130D.

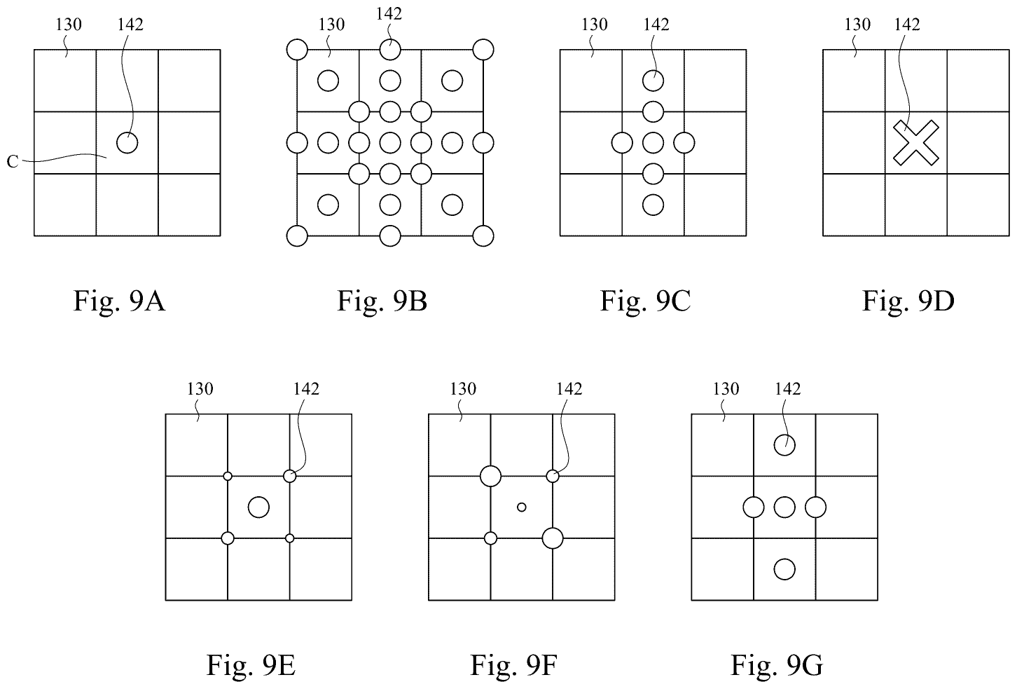

FIGS. 9A-9G illustrate various examples of top views of the nanopillars 142 in some embodiments of the present disclosure. The nanopillars 142A, 142B, 142C and 142D in FIGS. 8A and 8B may be replaced with any of the nanopillars 142 shown in FIGS. 9A-9G respectively. For example, refer to FIG. 9A. The nanopillars 142 may be over the center of the center region of the color filter unit 130. Refer to FIG. 9B, the nanopillars 142 may be over the top-left region, the top region, the top-right region, the left region, the center region, the right region, the bottom-left region, the bottom region, the bottom-right region. Refer to FIG. 9C, the nanopillars 142 may be over the top region, the center region, the bottom region and four edges of the center region. Refer to FIG. 9D, the nanopillars 142 may be over the center of the center region and may not be circle. Refer to FIG. 9E, the nanopillars 142 may be over the center and four corners of the center region. The diameter of the nanopillar 142 over the center of the center region may be the greatest, and the diameter of the nanopillars 142 over the top-left corner and the bottom-right corner of the center region may be the smallest. Refer to FIG. 9F, the nanopillars 142 may be over the center and four corners of the center region. The diameter of the nanopillar 142 over the center of the center region may be the greatest, and the diameter of the nanopillars 142 over the top-right corner and the bottom-left corner of the center region may be the smallest. Refer to FIG. 9G, the nanopillars 142 may be over the top region, the center region, the bottom region and two edges of the center region, such as the left edge and the right edge of the center region. The patterns of the nanopillars 142 are not limited to the patterns shown in FIGS. 9A-9G. As long as the pattern of the nanopillars 142 is centrosymmetric with a symmetric point at the center of the center region C, the pattern of the nanopillars 142 may be within the scope of the present disclosure.

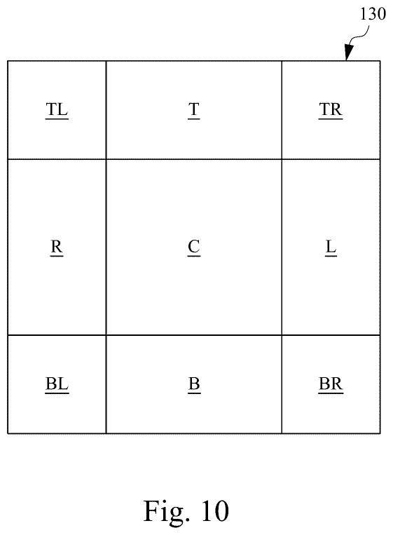

FIG. 10 illustrates a top view of the color filter unit 130 in some other embodiments of the present disclosure. Compared to FIG. 2B, the top-left region TL, the top region T, the top-right region TR, the left region L, the center region C, the right region R, the bottom-left region BL, the bottom region B, the bottom-right region BR do not all have the same area sizes in FIG. 10, and each of the color filter unit 130 may correspond with 16 photodiodes. Specifically, the top region T, the left region L, the right region R and the bottom region B have same area sizes, the top-left region TL, the top-right region TR, the bottom-left region BL and the bottom-right region BR have same area sizes, and an area ratio of the center region C, the top region T and the top-left region TL is 4:2:1. The center region C may correspond with 4 photodiodes, each of the top region T, the left region L, the right region R and the bottom region B may correspond with 2 photodiodes respectively, and each of the top-left region TL, the top-right region TR, the bottom-left region BL and the bottom-right region BR may correspond with 1 photodiode respectively.

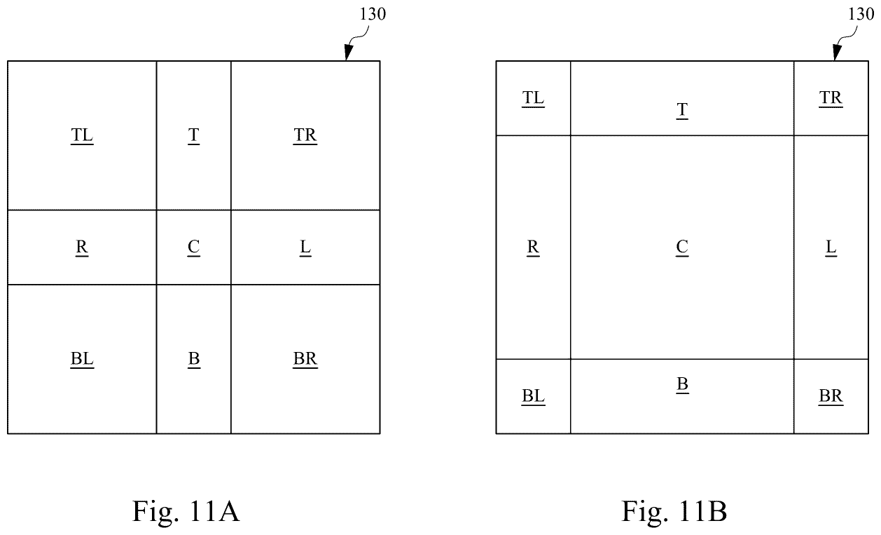

FIGS. 11A-11B illustrate a top view of the color filter unit 130 in some other embodiments. Compared to FIG. 2B, the top-left region TL, the top region T, the top-right region TR, the left region L, the center region C, the right region R, the bottom-left region BL, the bottom region B, the bottom-right region BR do not all have the same area sizes in FIGS. 11A-11B, and each of the color filter unit 130 in FIGS. 11A-11B may correspond with 25 photodiodes.

Specifically, in FIG. 11A, the top region T, the left region L, the right region R and the bottom region B have same area sizes, the top-left region TL, the top-right region TR, the bottom-left region BL and the bottom-right region BR have same area sizes, and an area ratio of the center region C, the top region T and the top-left region TL is 1:2:4. The center region C may correspond with 1 photodiode, each of the top region T, the left region L, the right region R and the bottom region B may correspond with 2 photodiodes respectively, and each of the top-left region TL, the top-right region TR, the bottom-left region BL and the bottom-right region BR may correspond with 4 photodiodes respectively.

In FIG. 11B, the top region T, the left region L, the right region R and the bottom region B have same area sizes, the top-left region TL, the top-right region TR, the bottom-left region BL and the bottom-right region BR have same area sizes, and an area ratio of the center region C, the top region T and the top-left region TL is 9:3:1. The center region C may correspond with 4 photodiodes, each of the top region T, the left region L, the right region R and the bottom region B may correspond with 2 photodiodes respectively, and each of the top-left region TL, the top-right region TR, the bottom-left region BL and the bottom-right region BR may correspond with 1 photodiode respectively.

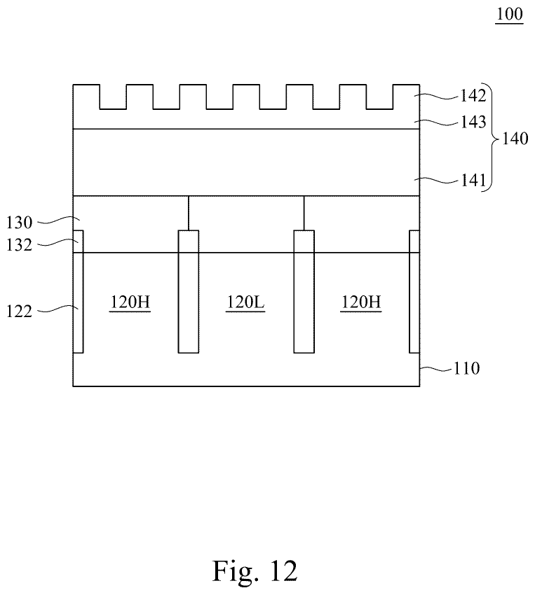

FIG. 12 illustrates a cross-section of an image sensor 100 in some other embodiments. The light intensity distributor 140 further includes a dielectric layer 143 under the nanopillars 142 and over the under layer 141, and the dielectric layer 143 and the nanopillars 142 are made of same materials. The refractive index of the nanopillars 142 and the dielectric layer 143 is larger than a refractive index of the under layer 141 and a refractive index of the surrounding environment. The dielectric layer 143 may be used to adjust the height of the nanopillars 142 to enhance the contrast between the light intensity received by the low sensitivity photodiode 120L and the high sensitivity photodiode 120H. Specifically, the dielectric layer 143 and the nanopillars 142 may be formed by forming a nanopillar material layer over the under layer, and then etching the nanopillar material layer to form the dielectric layer 143 and the nanopillars 142. The nanopillar material layer is not completely etched, and thus the dielectric layer 143 remains under the nanopillars 142. The height of the nanopillars 142 depends on degree of etching of the nanopillar material layer. Other details of the image sensor 100 may be similar to any image sensors 100 mentioned in FIGS. 2A-5B and are not described therein.

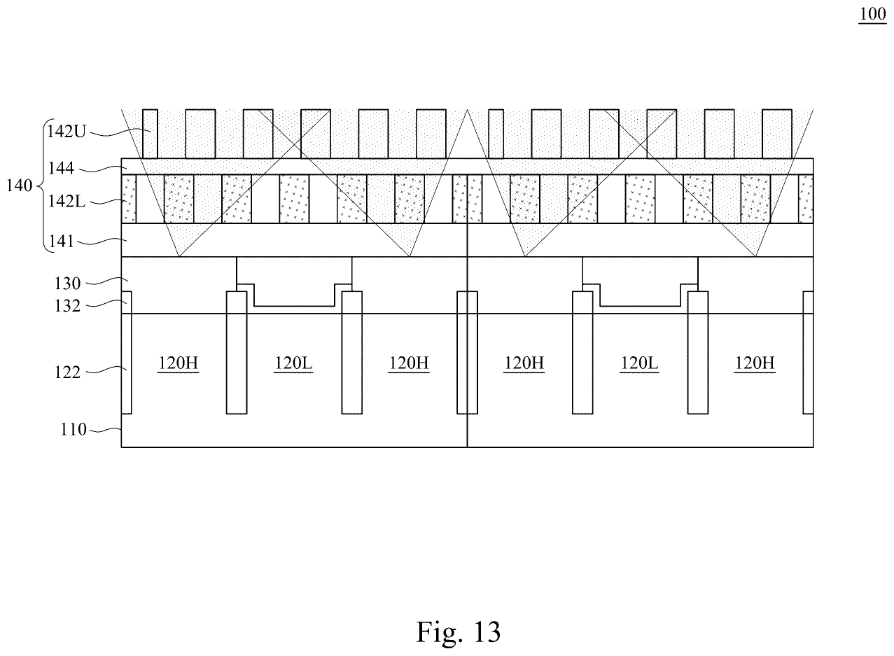

FIG. 13 illustrates a cross-section of an image sensor 100 in some other embodiments. The nanopillars 142 include a plurality of lower nanopillars 142L over the color filter unit 130 and a plurality of upper nanopillars 142U over the lower nanopillars 142L. A dielectric layer 144 may be between the upper nanopillars 142U and the lower nanopillars 142L. The upper nanopillars 142U may be or may not be aligned with the lower nanopillars 142L. The arrangement and the shape of the upper nanopillars 142U and the lower nanopillars 142L may be designed to enhance the contrast between the light intensity received by the low sensitivity photodiode 120L and the high sensitivity photodiode 120H. Other details of the image sensor 100 may be similar to any image sensors 100 mentioned in FIGS. 2A-5B and are not described therein.

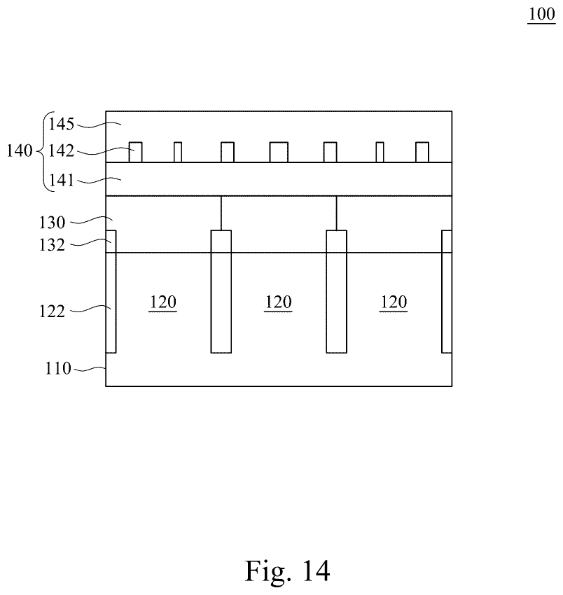

FIG. 14 illustrates a cross-section of an image sensor 100 in some other embodiments. The light intensity distributor further includes a protective layer 145 over the nanopillars 142, the nanopillars 142 are embedded in the protective layer 145, and a refractive index of the nanopillars 142 is larger than a refractive index of the protective layer 145. The protective layer 145 may be used to protect the nanopillars 142 from being damaged. Other details of the image sensor 100 may be similar to any image sensor 100 mentioned in FIGS. 2A-5B and are not described therein.

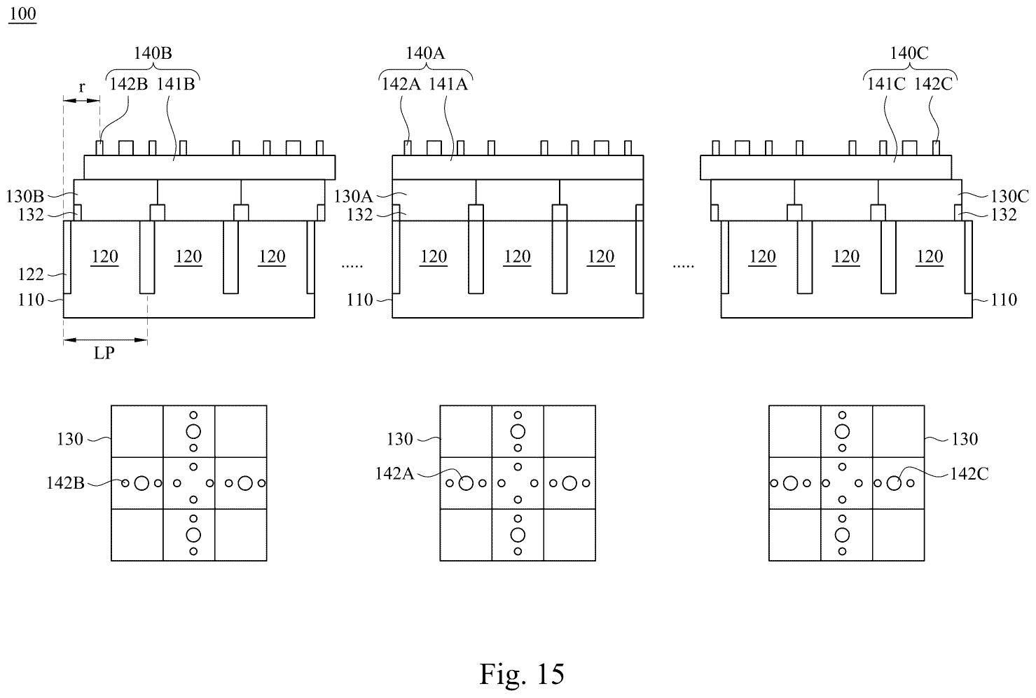

FIG. 15 illustrates a cross-section of an image sensor 100 in some other embodiments. The image sensor 100 includes the substrate 110, the photodiodes 120, the color filter units 130A, 130B and 130C, the light shields 132, and the light intensity distributors 140A, 140B and 140C. The photodiodes 120 are in the substrate 110. The color filter units 130A, 130B and 130C are over the photodiodes 120 in a cross-section view. The color filter units 130A, 130B and 130C have the same color, but are at different location of the image sensor 100 in a top view. The color filter units 130B and 130C are at the edge of the image sensor 100, and the color filter unit 130A is at the center of the image sensor 100. The light intensity distributor 140A is over the color filter unit 130A, the light intensity distributor 140B is over the color filter unit 130B, and the light intensity distributor 140C is over the color filter unit 130C. The color filter unit 130B is laterally shifted relative to the photodiodes 120 under the color filter units 130B towards a center of the image sensor 100, and the light intensity distributor 140B is laterally shifted relative to the color filter unit 130B towards the center of the image sensor 100. Similarly, the color filter unit 130C is laterally shifted relative to the photodiodes 120 under the color filter units 130C towards a center of the image sensor 100, and the light intensity distributor 140C is laterally shifted relative to the color filter unit 130C towards the center of the image sensor 100. The color filter unit 130A and the light intensity distributor 140A at the center of the image sensor 100 are not shifted in FIG. 15.

The light intensity distributor 140A includes the under layer 141A and the nanopillars 142A over the under layer 141A. The light intensity distributor 140B includes the under layer 141B and the nanopillars 142B over the under layer 141B. The light intensity distributor 140C includes the under layer 141C and the nanopillars 142C over the under layer 141C. The shifted distance r of the light intensity distributor 140B may be defined as the distance between the edge of the outmost deep trench isolation 122 and the center of the outmost nanopillar 142B. The shifted distance r of the light intensity distributor 140C may be defined as the distance between the edge of the outmost deep trench isolation 122 and the center of the outmost nanopillar 142C. The shifted distance r may be 0.3 to 0.5 times of a length LP of a pixel. The length LP of the pixel is defined as the distance between the adjacent deep trench isolations 122. The shifting of the color filter unit 130B and 130C and the light intensity distributor 140B and 140C is used to compensate the chief ray angle (CRA) effect. Specifically, light received by the different location of the image sensor 100, especially the edge of the image sensor 100, may be converged to the photodiodes 120 at different location after the shifting of the color filter unit 130B and 130C. If the color filter unit 130B and 130C and the light intensity distributor 140B and 140C are not shifting to compensate the chief ray angle effect, the light may not be converged to the photodiodes 120 properly.

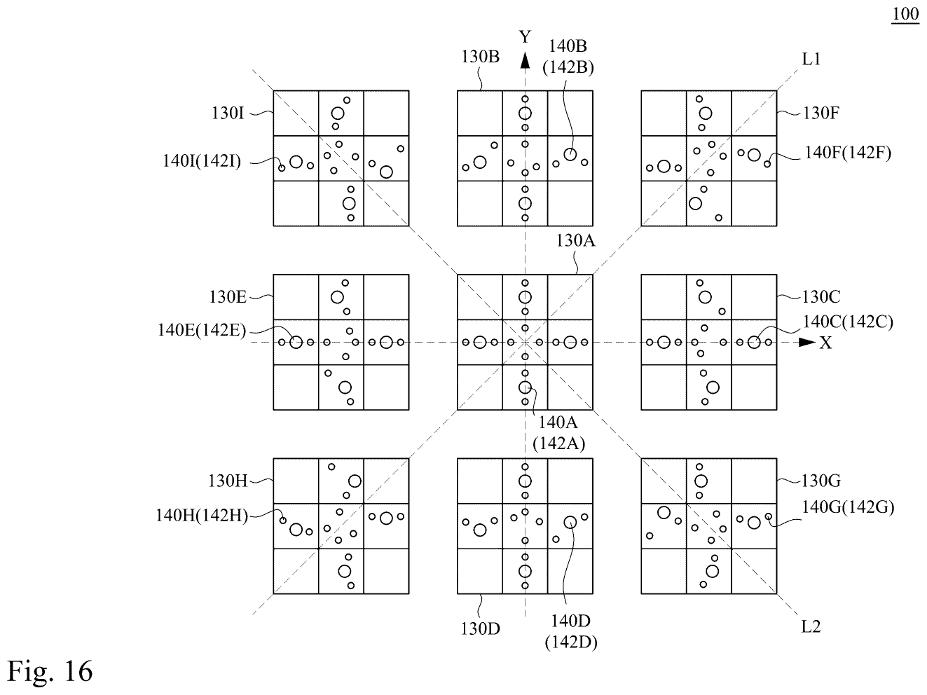

FIG. 16 illustrates a top view of an image sensor 100 in some other embodiments. The image sensor 100 includes color filter units 130A-130I and light intensity distributors 140A-140I over the color filter units 130A-130I respectively. The color filter units 130A-130I have the same color, but are at different locations of the image sensor 100. The light intensity distributors 140A-140I over the color filter units 130A-130I include the nanopillars 142A-142I respectively. The color filter units 130A-130I are over the photodiodes over the substrate, and the photodiodes and the substrate are similar to those shown in any of FIGS. 2A-5B. The light intensity distributor 140A is at the center of the image sensor 100, and the light intensity distributors 140B-140E are at the X-axis or the Y-axis. The distance between centers of the light intensity distributor 140B and the light intensity distributor 140A, a distance between centers of the light intensity distributor 140C and the light intensity distributor 140A, a distance between centers of the light intensity distributor 140D and the light intensity distributor 140A and a distance between centers of the light intensity distributor 140E and the light intensity distributor 140A are the same.

The nanopillars 142B-142E may be shifted to compensate the CRA effect. Specifically, the nanopillars 142B-142E on the X-axis and the Y-axis may be shifted along the X-axis and the Y-axis, and the nanopillars 142B-142E not on the X-axis and the Y-axis may be shifted in any direction. After shifting the nanopillars 142B-142E, the pattern of the nanopillars 142B-142E follows the following rule. An angle between a line passing through the centers of the light intensity distributor 140B and the light intensity distributor 140A (such as Y-axis) and a line passing through the centers of the light intensity distributor 140C and the light intensity distributor 140A (such as X-axis) is 90 degrees, and a pattern of the nanopillars 142B is the same as a pattern of the nanopillars 142C after rotating the light intensity distributor 140B 90 degrees clockwise. Similarly, an angle between a line passing through the centers of the light intensity distributor 140C and the light intensity distributor 140A (such as X-axis) and a line passing through the centers of the light intensity distributor 140D and the light intensity distributor 140A (such as Y-axis) is 90 degrees, and a pattern of the nanopillars 142C is the same as a pattern of the nanopillars 142D after rotating the light intensity distributor 140C 90 degrees clockwise. An angle between a line passing through the centers of the light intensity distributor 140D and the light intensity distributor 140A (such as Y-axis) and a line passing through the centers of the light intensity distributor 140E and the light intensity distributor 140A (such as X-axis) is 90 degrees, and a pattern of the nanopillars 142D is the same as a pattern of the nanopillars 142E after rotating the light intensity distributor 140C 90 degrees clockwise. An angle between a line passing through the centers of the light intensity distributor 140E and the light intensity distributor 140A (such as X-axis) and a line passing through the centers of the light intensity distributor 140B and the light intensity distributor 140A (such as Y-axis) is 90 degrees, and a pattern of the nanopillars 142E is the same as a pattern of the nanopillars 142B after rotating the light intensity distributor 140E 90 degrees clockwise.

Moreover, the light intensity distributors 140F-140I are not at the X-axis or the Y-axis, the line L1 passing through the centers of the light intensity distributors 140F and the light intensity distributors 140H rotates 45 degrees counterclockwise from the X-axis, and the line L2 passing through the centers of the light intensity distributors 140G and the light intensity distributors 140I rotates 45 degrees clockwise from the X-axis. A distance between centers of the light intensity distributor 140F and the light intensity distributor 140A, a distance between centers of the light intensity distributor 140G and the light intensity distributor 140A, a distance between centers of the light intensity distributor 140H and the light intensity distributor 140A and a distance between centers of the light intensity distributor 140I and the light intensity distributor 140A are the same.

The nanopillars 142F-142I may be shifted to compensate the CRA effect. Specifically, the nanopillars 142F-142I may be shifted in any direction. After shifting the nanopillars 142F-142I, the pattern of the nanopillars 142F-142I follows the following rule. An angle between a line passing through the centers of the light intensity distributor 140F and the light intensity distributor 140A (such as line L1) and a line passing through the centers of the light intensity distributor 140G and the light intensity distributor 140A (such as line L2) is 90 degrees, and a pattern of the nanopillars 142F is the same as a pattern of the nanopillars 142G after rotating the light intensity distributor 140F 90 degrees clockwise. Similarly, an angle between a line passing through the centers of the light intensity distributor 140G and the light intensity distributor 140A (such as line L2) and a line passing through the centers of the light intensity distributor 140H and the light intensity distributor 140A (such as line L1) is 90 degrees, and a pattern of the nanopillars 142G is the same as a pattern of the nanopillars 142H after rotating the light intensity distributor 140G 90 degrees clockwise. An angle between a line passing through the centers of the light intensity distributor 140H and the light intensity distributor 140A (such as line L1) and a line passing through the centers of the light intensity distributor 140I and the light intensity distributor 140A (such as line L2) is 90 degrees, and a pattern of the nanopillars 142H is the same as a pattern of the nanopillars 142I after rotating the light intensity distributor 140H 90 degrees clockwise. An angle between a line passing through the centers of the light intensity distributor 140I and the light intensity distributor 140A (such as line L2) and a line passing through the centers of the light intensity distributor 140F and the light intensity distributor 140A (such as line L1) is 90 degrees, and a pattern of the nanopillars 142I is the same as a pattern of the nanopillars 142F after rotating the light intensity distributor 140I 90 degrees clockwise.

As mentioned above, the image sensor in some embodiments of the present disclosure includes a light intensity distributor. The light intensity distributor includes the nanopillars, and the nanopillars of the present disclosure may be formed by a simple manufacturing process to reduce the cost of manufacturing the light intensity distributor. The light intensity distributor may directly distribute the light received by the image sensor into different regions without shielding certain portions of the photodiodes under the light intensity distributor. Therefore, there is no significant energy loss with the image sensor in some embodiments of the present disclosure. The light intensity distributor and the nanopillar may further be shifted to compensate the CRA effect to ensure that the photodiodes under the light intensity distributor may be able to receive light.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An image sensor, comprising:
a substrate;
a plurality of first photodiodes in the substrate;
a first color filter unit over the substrate in a cross-section view, the first color filter unit comprising a top-left region, a top region, a top-right region, a left region, a center region, a right region, a bottom-left region, a bottom region, and a bottom-right region in a top view; and
a first light intensity distributor over the first color filter unit, wherein the first light intensity distributor comprises a plurality of first nanopillars to distribute light to make the center region has a highest or a lowest optical intensity.

2. The image sensor of claim 1, wherein the first nanopillars comprise a first pattern of the first nanopillars in the left region and a second pattern of the first nanopillars in the right region, the first pattern of the first nanopillars is symmetric to the second pattern of the first nanopillars, with a symmetric axis passing through centers of the top region and the bottom region.

3. The image sensor of claim 1, wherein the first nanopillars comprise a first pattern of the first nanopillars in the top region and a second pattern of the first nanopillars in the bottom region, the first pattern of the first nanopillars is symmetric to the second pattern of the first nanopillars, with a symmetric axis passing through centers of the left region and the right region.

4. The image sensor of claim 1, wherein the first nanopillars comprise a first pattern of the first nanopillars in the top-left region and a second pattern of the first nanopillars in the bottom-right region, the first pattern of the first nanopillars is symmetric to the second pattern of the first nanopillars, with a symmetric axis passing through centers of the top-right region and the bottom-left region.

5. The image sensor of claim 1, wherein the first nanopillars comprise a first pattern of the first nanopillars in the top-right region and a second pattern of the first nanopillars in the bottom-left region, the first pattern of the first nanopillars is symmetric to the second pattern of the first nanopillars, with a symmetric axis passing through centers of the top-left region and the bottom-right region.

6. The image sensor of claim 1, wherein the first nanopillars comprise a first pattern of the first nanopillars in the left region, the right region, the top region, the bottom region, the top-left region, the top-right region, the bottom-left region and the bottom-right region and a second pattern of the first nanopillars in the center region, the first pattern of the first nanopillars is used to converge light to the left region, the right region, the top region, the bottom region, the top-left region, the top-right region, the bottom-left region and the bottom-right region, the second pattern of the first nanopillars is used to disperse light from the center region, the first pattern of the first nanopillars is centrosymmetric with a symmetric point at the center of the center region, and individual patterns of the first nanopillars in the left region, the right region, the top region, the bottom region, the top-left region, the top-right region, the bottom-left region and the bottom-right region are the same or different.

7. The image sensor of claim 1, wherein the first nanopillars comprise a first pattern of the first nanopillars in the left region, the right region, the top region, the bottom region, the top-left region, the top-right region, the bottom-left region and the bottom-right region and a second pattern of the first nanopillars in the center region, the first pattern of the first nanopillars are used to disperse light from the left region, the right region the top region, the bottom region, the top-left region, the top-right region, the bottom-left region and the bottom-right region, the second pattern of the first nanopillars is used to converge light to the center region, the first pattern of the first nanopillars is centrosymmetric with a symmetric point at the center of the center region, and individual patterns of the first nanopillars in the left region, the right region, the top region, the bottom region, the top-left region, the top-right region, the bottom-left region and the bottom-right region are the same or different.

8. The image sensor of claim 1, wherein the first nanopillars comprise first central nanopillars at centers of the top region, the bottom region, the left region, the right region, the top-left region, the top-right region, the bottom-left region and the bottom-right region and a second central nanopillar at a center of the center region, and a volume of each of the first central nanopillars is more than 4 times larger than a volume of the second central nanopillar.

9. The image sensor of claim 1, wherein the first nanopillars comprise first central nanopillars at centers of the top region, the bottom region, the left region, the right region, the top-left region, the top-right region, the bottom-left region and the bottom-right region and a second central nanopillar at a center of the center region, and a volume of each of the first central nanopillars is less than 4 times smaller than a volume of the second central nanopillar.

10. The image sensor of claim 1, wherein the first light intensity distributor further comprises:
an under layer under the first nanopillars, and a refractive index of the first nanopillars is larger than a refractive index of the under layer.

11. The image sensor of claim 10, wherein the first light intensity distributor further comprises a dielectric layer under the first nanopillars and over the under layer, and the dielectric layer and the first nanopillars are made of same materials.

12. The image sensor of claim 1, wherein the first nanopillars comprise a plurality of lower nanopillars over the first color filter unit and a plurality of upper nanopillars over the lower nanopillars.

13. The image sensor of claim 1, wherein the first light intensity distributor further comprises a protective layer over the first nanopillars, the first nanopillars are embedded in the protective layer, and a refractive index of the first nanopillars is larger than a refractive index of the protective layer.

14. The image sensor of claim 1, wherein the first light intensity distributor further comprises a light-shielding layer,
wherein the light-shielding layer is under the center region of the first color filter unit when the center region has the lowest optical intensity, or
the light-shielding layer is under at least one of the top-left region, the top region, the top-right region, the left region, the right region, the bottom-left region, the bottom region, and the bottom-right region of the first color filter unit when the center region has the highest optical intensity.

15. The image sensor of claim 1, wherein the top region, the left region, the right region and the bottom region have same area sizes, the top-left region, the top-right region, the bottom-left region and the bottom-right region have same area sizes, an area ratio of the center region, the top region and the top-left region is 1:1:1, and each of the top-left region, the top region, the top-right region, the left region, the center region, the right region, the bottom-left region, the bottom region, and the bottom-right region corresponds with one of the first photodiodes respectively.

16. The image sensor of claim 1, wherein the top region, the left region, the right region and the bottom region have same area sizes, the top-left region, the top-right region, the bottom-left region and the bottom-right region have same area sizes, an area ratio of the center region, the top region and the top-left region is 4:2:1, and the center region corresponds with four of the first photodiodes, each of the top region, the left region, the right region and the bottom region corresponds with two of the first photodiodes respectively, and each of the top-left region, the top-right region, the bottom-left region and the bottom-right region corresponds with one of the first photodiodes respectively.

17. The image sensor of claim 1, wherein the top region, the left region, the right region and the bottom region have same area sizes, the top-left region, the top-right region, the bottom-left region and the bottom-right region have same area sizes, an area ratio of the center region, the top region and the top-left region is 9:3:1, and the center region corresponds with nine of the first photodiodes, each of the top region, the left region, the right region and the bottom region corresponds with three of the first photodiodes respectively, and each of the top-left region, the top-right region, the bottom-left region and the bottom-right region corresponds with one of the first photodiodes respectively.

18. The image sensor of claim 1, wherein the top region, the left region, the right region and the bottom region have same area sizes, the top-left region, the top-right region, the bottom-left region and the bottom-right region have same area sizes, an area ratio of the center region, the top region and the top-left region is 1:2:4, and the center region corresponds with one of the first photodiodes, each of the top region, the left region, the right region and the bottom region corresponds with two of the first photodiodes respectively, and each of the top-left region, the top-right region, the bottom-left region and the bottom-right region corresponds with four of the first photodiodes respectively.

19. The image sensor of claim 1, wherein the first color filter unit is laterally shifted relative to the first photodiodes towards a center of the image sensor, and the first light intensity distributor is laterally shifted relative to the first color filter unit towards the center of the image sensor.

20. The image sensor of claim 1, further comprising:
a plurality of second photodiodes in the substrate;
a second color filter unit over the substrate and the second photodiodes;
a second light intensity distributor over the second color filter unit, wherein the second light intensity distributor comprises a plurality of second nanopillars;
a plurality of third photodiodes in the substrate;
a third color filter unit over the substrate and the third photodiodes, wherein the first color filter unit, the second color filter unit and the third color filter unit have the same color, but are at different locations of the image sensor; and
a third light intensity distributor over the third color filter unit, wherein the third light intensity distributor comprises a plurality of third nanopillars, a distance between centers of the second light intensity distributor and the first light intensity distributor and a distance between centers of the third light intensity distributor and the first light intensity distributor are the same, an angle between a line passing through the centers of the second light intensity distributor and the first light intensity distributor and a line passing through the centers of the third light intensity distributor and the first light intensity distributor is 90 degrees, and a pattern of the second nanopillars is the same as a pattern of the third nanopillars after rotating the second light intensity distributor 90 degrees clockwise.
